(19) United States
(12) Patent Application Publication
(10) Pub. No.: US 2016/0204133 A1
(43) Pub. Date: Jul. 14, 2016

(54) SUBSTRATE FOR CURVED DISPLAY DEVICE AND MANUFACTURING METHOD THEREOF

(71) Applicant: Samsung Display Co., Ltd., Yongin-City (KR)

(72) Inventors: Seung KIM, Seongnam-si (KR); Seung Ho KIM, Asan-si (KR); Jeong Woo PARK, Yongin-si (KR); Sang Hoon AHN, Seoul (KR); Jong Hoon YEUM, Seoul (KR); Hoi Kwan LEE, Anseong-si (KR); Joo Woan CHO, Seongnam-si (KR)

(21) Appl. No.: 14/805,233

(22) Filed: Jul. 21, 2015

(30) Foreign Application Priority Data
Jan. 8, 2015 (KR) 10-2015-0002707

(51) Int. Cl. H01L 27/12; C03C 17/10; H01L 51/00; C03B 33/09; H01L 27/32; C03C 17/04; C03C 17/00

(52) U.S. Cl. CPC H01L 27/1218; C03C 17/04; C03C 17/10; C03C 17/001; C03B 33/091; H01L 27/3276; H01L 51/0096; H01L 27/3248

(57) ABSTRACT

Disclosed is a substrate for a curved display device, including: an alkali-free glass substrate that does not contain an alkali metal oxide; and an inorganic coating part formed on at least one of a display surface and a lateral surface of the alkali-free glass substrate, and having a larger value of a coefficient of thermal expansion than that of the glass substrate.

### CROSS-REFERENCE TO RELATED APPLICATION

This application claims priority to and the benefit of Korean Patent Application No. 10-2015-0002707 filed in the Korean Intellectual Property Office on Jan. 8, 2015, the entire contents of which are incorporated herein by reference.

### BACKGROUND

(a) Field

The present disclosure relates to a substrate for a curved display device and a manufacturing method thereof.

(b) Description of the Related Art

Types of display devices include a liquid crystal display (LCD) and an organic light emitting display (OLED).

The liquid crystal display generates an electric field in a liquid crystal layer disposed therein by applying a voltage to field generating electrodes, such as a pixel electrode and a common electrode, disposed on opposite sides of the liquid crystal layer. The strength of the generated electric field determines the alignment direction of the liquid crystal molecules in the liquid crystal layer, which in turn determines the polarization of incident light by the liquid crystal molecules. The incident light is generally received from a separate light source (e.g., a backlight). Thus, by controlling the strength of the generated field, and thereby controlling the polarization of incident light, the liquid crystal display is able to display an image. In contrast, the organic light emitting display has a self-emission characteristic and does not require a separate light source, and displays an image through a display substrate in which thin film transistors and organic light emitting elements are formed.

As the size of the display device increases, such as for use in large televisions screens, a problem in which the center of the screen appears different from the left and right ends of the screen becomes increasingly noticeable.

To compensate for the difference in views, a curved display device may be formed by bending the display device in a concave type or convex type. For example, for a portrait type of display device in which its horizontal length is smaller than its vertical length, the screen may curve along the vertical direction with respect to a viewer. Conversely, for a landscape type of display device in which its vertical length is smaller than its horizontal length, the screen may curve along the horizontal direction.

However, when the display device is formed in a curved shape by bending the screen thereof, compressive stress is applied to an inner side of the curved surface and tensile stress is applied to an outer side in the substrate. As a result of the stress, a crack may be generated in the substrate and cause damage to a panel of the display device.

The above information disclosed in this Background section is only for enhancement of understanding of the background of the disclosure and therefore may contain information that does not form the prior art that is already known in this country to a person of ordinary skill in the art.

### SUMMARY

The present system and method decrease damage to a panel due to a crack formed by compressive stress applied to an inner side of a glass substrate by selectively applying an inorganic coating part having a predetermined value of coefficient of thermal expansion to the glass substrate.

An exemplary embodiment of the present system and method provides a substrate for a curved display device, including: an alkali-free glass substrate that does not contain an alkali metal oxide; and an inorganic coating part formed on at least one of a display surface and a lateral surface of the alkali-free glass substrate, and having a larger value of a coefficient of thermal expansion than that of the glass substrate.

A value of a coefficient of thermal expansion of the alkali-free glass substrate may be 40×10⁻⁷/° C. or lower.

A difference in values of the coefficient of thermal expansion between the alkali-free glass substrate and the inorganic coating part may be less than 40×10⁻⁷/° C.

The inorganic coating part may include a metal, glass, or a combination thereof.

The inorganic coating part may be formed by sintering frit.

The inorganic coating part may be formed at an edge portion of the alkali-free glass substrate.

The inorganic coating part may be locally formed at the edge portion of the alkali-free glass substrate.

Another exemplary embodiment of the present system and method provides a method of manufacturing a substrate for a curved display device, the method including: applying an inorganic paste onto at least one of a display surface and a lateral surface of an alkali-free glass substrate that does not contain an alkali metal oxide; and sintering the inorganic paste, in which the inorganic paste contains a component having a larger value of a coefficient of thermal expansion than that of the alkali-free glass substrate.

The sintering may be performed by using a laser heat source.

Yet another exemplary embodiment of the present system and method provides a curved display device, including: the substrate for the curved display device; a thin film transistor positioned on the substrate for the curved display device; and a pixel electrode electrically connected to the thin film transistor.

The curved display device may further include: a common electrode facing the pixel electrode; and a light emission layer interposed between the pixel electrode and the common electrode.

Still yet another exemplary embodiment of the present system and method provides a method of cutting a substrate for a curved display device, the method including: applying an inorganic paste onto a part of a surface of an alkali-free glass substrate that does not contain an alkali metal oxide; sintering the inorganic paste to form sintered inorganic paste; and cutting the alkali-free glass substrate along a portion at which the sintered inorganic paste is formed.

According to the exemplary embodiments of the present system and method, it is possible to prevent a substrate for a curved display device from being damaged due to a crack.

### BRIEF DESCRIPTION OF THE DRAWINGS

FIGS. 1A, 1B, and 1C are diagrams illustrating a frit application form of an edge portion in a substrate for a curved display device according to exemplary embodiments of the present system and method.

FIG. 2 is a diagram illustrating a process of sintering frit according to an exemplary embodiment of the present system and method.

FIG. 3 is a diagram illustrating a frit application form of a rear surface of a panel in a cutting method of a substrate for a curved display device according to another exemplary embodiment of the present system and method.

FIG. 4 is a diagram illustrating a cutting line for cutting a substrate for the curved display device according to an exemplary embodiment of the present system and method.

FIG. 5 is a diagram illustrating stress distribution of a frit applied portion in a substrate for a curved display device according to an exemplary embodiment of the present system and method.

FIGS. 6 and 7 are diagrams for describing stress distribution of a frit applied portion in a substrate for a curved display device according to an exemplary embodiment of the present system and method.

FIG. 8 is a cross-sectional view of a curved display device according to yet another exemplary embodiment of the present system and method.

### DETAILED DESCRIPTION OF THE EMBODIMENTS

In the following detailed description, certain exemplary embodiments of the present system and method are shown and described for the purpose of illustration. As those skilled in the art would realize, the described embodiments may be modified in various different ways, all without departing from the spirit or scope of the present system and method.

In the drawings, the thickness of layers, films, panels, regions, etc., is exaggerated for clarity. Like reference numerals designate like elements throughout the specification. When an element such as a layer, film, region, or substrate is referred to as being “on” another element, it may be directly on the other element, or intervening elements may also be present. In contrast, when an element is referred to as being “directly on” another element, there are no intervening elements present.

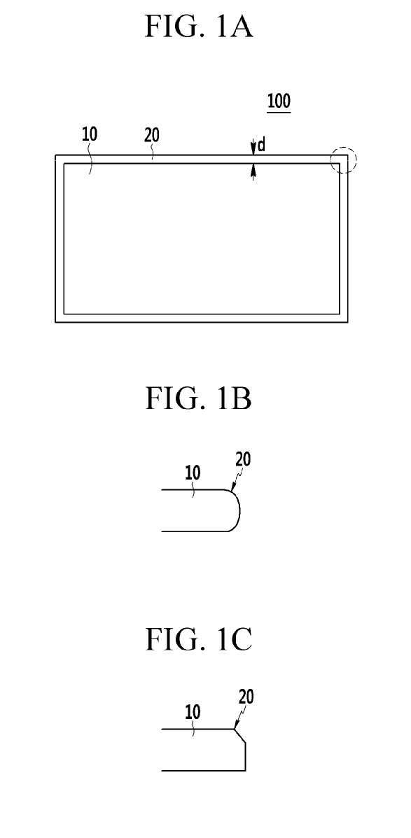

Hereinafter, a substrate for a curved display device according to an exemplary embodiment of the present system and method is described with reference to FIGS. 1A, 1B, and 1C.

A substrate 100 for a curved display device according to an exemplary embodiment of the present system and method includes an alkali-free glass substrate 10 and an inorganic coating part 20 formed on a display surface and/or a lateral surface of the alkali-free glass substrate 10. As used herein, a display surface refers to a surface overlaying the area of the display device where images are displayed.

The alkali-free glass substrate 10 is formed of an alkali-free glass material in which an alkali metal oxide is not contained.

The inorganic coating part 20 may be formed on a lateral surface of the alkali-free glass substrate 10, such as an edge portion of the alkali-free glass substrate 10, as illustrated in FIG. 1A. The inorganic coating part 20 may be formed of a material of a metal, glass, or a combination thereof. For example, the inorganic coating part 20 may be formed by sintering frit.

According to an exemplary embodiment, the inorganic coating part 20 has a larger value of coefficient of thermal expansion (CTE) than that of the glass substrate 10. For example, the value of the CTE of the alkali-free glass substrate 10 may be 40×10⁻⁷/° C. or lower.

In general, in the glass substrate, a crack is easily generated in a portion to which tensile stress is applied.

According to an exemplary embodiment of the present system and method, it is possible to apply temporary a compressive stress, which is exhibited according to a thermal property, into the alkali-free glass substrate 10 by locally or selectively sintering a material (e.g., inorganic coating part 20) having a relatively larger value of the CTE than that of the alkali-free glass substrate 10 on the surface or the edge portion of the alkali-free glass substrate 10. Applying a compressive stress in this manner prevents an initially generated crack on the surface of the alkali-free glass substrate 10 from growing, or otherwise slows its growth, or prevents a panel of the curved display device from being damaged due to a crack.

Furthermore, because the compressive stress applied by the inorganic coating part 20 reduces the tensile stress in the alkali-free glass substrate 10, energy for generating or growing a crack is decreased or removed. As a result, it is possible to prevent or delay the generation of the crack in the substrate 100, and to enhance the durability and reliability of the curved substrate 100.

According to an exemplary embodiment, as long as the value of the CTE of the inorganic coating part 20 is larger than the value of the CTE of the glass substrate 10, the value of the CTE of the inorganic coating part 20 is not otherwise limited. According to another exemplary embodiment, the difference in the value of the CTE of the alkali-free glass substrate 10 and the value of the CTE of the inorganic coating part 20 may be controlled to less than, for example, 40×10⁻⁷/° C. Controlling the difference in the CTE values prevents or otherwise reduces unnecessary force applied to the panel.

Referring to FIGS. 1A, 1B, and 1C, the inorganic coating part 20 is formed by, for example, applying the frit onto a rear surface of the alkali-free glass substrate 10 and sintering the frit. The edge portion of the alkali-free glass substrate 10 may have, for example, a round type, such as shown in the cross-sectional view of FIG. 1B taken along line I-I of FIG. 1A, or a chamfer cut type, such as shown in the cross-section view of FIG. 1C taken along line I-I.

Referring to FIG. 1A, a width d and a thickness to which the inorganic coating part 20 is applied are not limited. For example, a thickness of the frit (wet frit) before being dried may be processed to be several tens of micrometers (μm) or lower, and a thickness of the frit (dry frit) after being dried may be processed to be 10 μm or lower, but the width d and the thickness to which the inorganic coating part 20 is applied are not limited thereto.

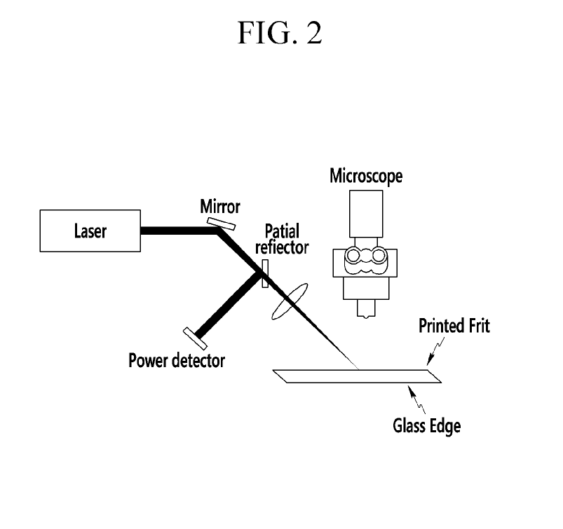

The sintering may be performed by locally or selectively applying a laser heat source to the edge portion of the alkali-free glass substrate 10. That is, the inorganic coating part 20 may be formed to be discontinuous along the edge portion of the alkali-free glass substrate 10 in discrete areas. FIG. 2 is a reference diagram illustrating a process of sintering frit by using laser.

Hereinafter, a method of manufacturing a substrate for a curved display device according to another exemplary embodiment is described.

Unless being described to the contrary, descriptions of an alkali-free glass substrate and an inorganic coating part are the same as the above descriptions.

A method of manufacturing a substrate for a curved display device according to another exemplary embodiment includes applying an inorganic paste on a display surface and/or a lateral surface of an alkali-free glass substrate, which does not contain an alkali metal oxide, and sintering the inorganic paste.

The inorganic paste contains an ingredient having a larger value of the CTE than that of the alkali-free glass substrate. The inorganic paste may be applied on an edge portion of the alkali-free glass substrate, and then may be selectively sintered. The inorganic paste may contain a metal, a glass ingredient, or a combination thereof, for example, frit.

The sintering may be performed by using a laser heat source, and the inorganic paste may be sintered by selectively applying the laser to an area where the inorganic coating part is desired to be applied. The process of sintering the frit by using the laser is illustrated in FIG. 2. The frit sintered in the example may have a sealing property. In order to implement a curved shape after the sintering, a bending process may be performed. Resistance against tensile stress temporarily generated during the bending process may increase due to the sintering process of the frit performed before the bending operation, so that it is possible to prevent a panel from being damaged.

Hereinafter, a method of cutting a substrate for a curved display device according to yet another exemplary embodiment is described.

According to yet another exemplary embodiment, a method of cutting a substrate for a curved display device includes: applying an inorganic paste onto a part of a surface of an alkali-free glass substrate that does not contain an alkali metal oxide, sintering the inorganic paste, and cutting the alkali-free glass substrate along a portion in which the sintered inorganic paste is formed.

Descriptions of the alkali-free glass substrate and the inorganic paste are the same as the above description.

According to an exemplary embodiment, in a process of manufacturing the substrate for the curved display device, compressive stress may be formed by applying frit having a larger value of the CTE onto a portion of the substrate, which is desired to be cut, and sintering the frit before cutting the substrate. Then, when the panel is cut by using laser, the growth of a crack formed on the surface of the glass substrate during the cutting process due to the compressive stress applied to the surface of the glass substrate may be restricted. Further, it is possible to easily cut the panel due to a tensile stress layer formed on a rear surface of the glass substrate, which provides a good cutting surface. The cutting may be performed by a laser full cutting method.

According to an example, the frit having a CTE of 40×10⁻⁷/° C. or more may be applied onto a portion of the surface of the alkali-free glass substrate that is to be cut, and then the frit may be sintered by selectively applying laser. Here, the portion to which the frit is applied may be the rear surface of the alkali-free glass substrate, and a thickness of the frit (wet frit) before being dried may be processed to be several tens of μm or lower, and a thickness of the frit (dry frit) after being dried may be processed to be 10 μm or lower. The process of sintering the frit by using the laser is illustrated in FIG. 2. After the sintering is completed, the panel may be divided by using laser again. According to the example, after the frit is sintered, the cutting process may be immediately performed by mounting the laser in two stages.

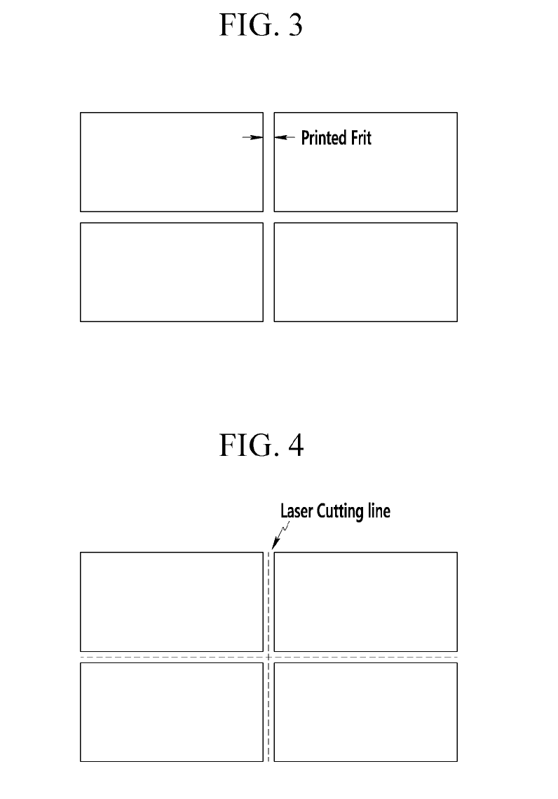

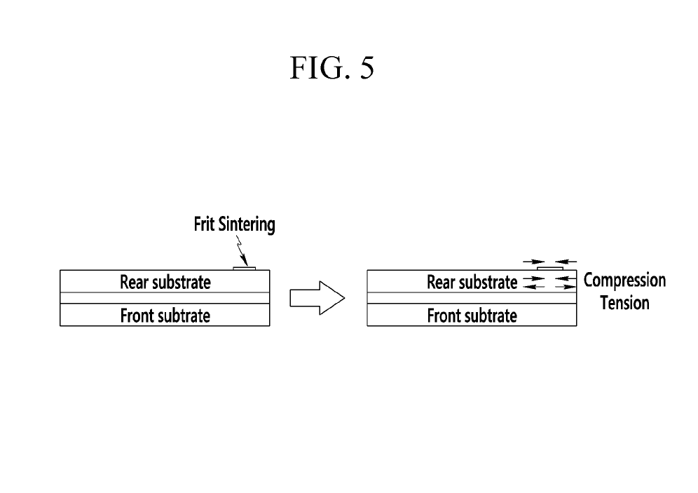

FIG. 3 is a diagram illustrating a frit application form of a rear surface of a panel in a cutting method of a substrate for a curved display device according to another exemplary embodiment of the present system and method. FIG. 4 is a diagram illustrating a cutting line for cutting the substrate for the curved display device according to an exemplary embodiment of the present system and method.

Further, according to an exemplary embodiment, a secondary processing, such as polishing, subsequent to the cutting process may not be necessary, and it is possible to improve long-term reliability by reducing tensile stress temporarily generated during the manufacturing of the substrate for the curved display device.

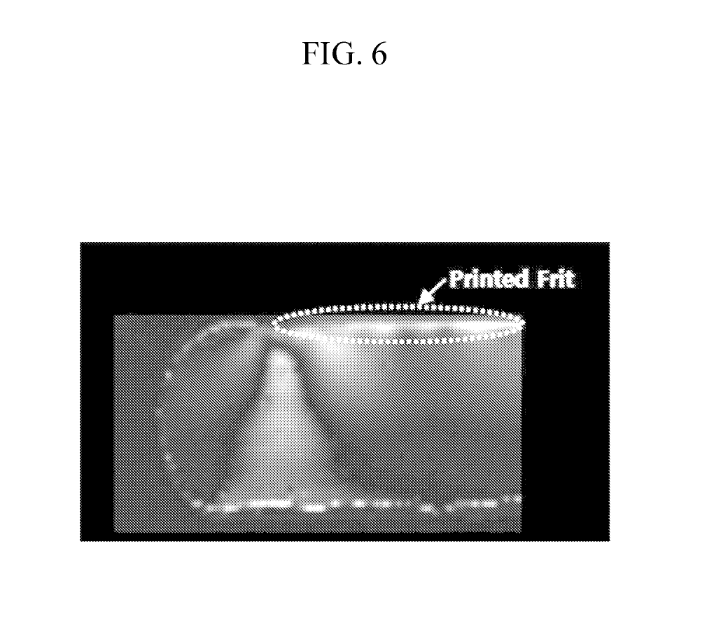

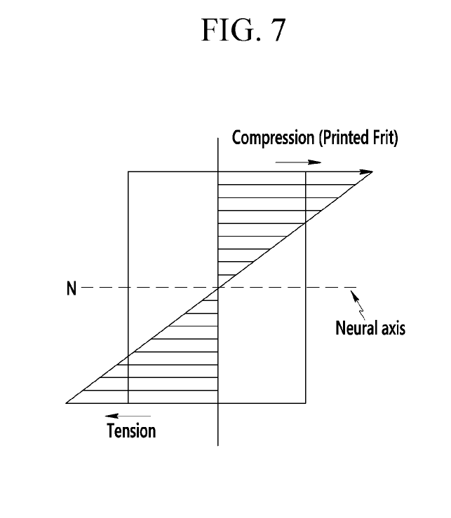

FIG. 5 is a cross-sectional view illustrating stress distribution of a frit applied portion in a substrate for a curved display device according to an exemplary embodiment of the present system and method. FIGS. 6 and 7 are diagrams for describing stress distribution of a frit applied portion in a substrate for a curved display device according to an exemplary embodiment of the present system and method. Referring to FIG. 5, it can be seen that when a material having a larger CTE than that of a glass substrate is sintered and bonded to the glass substrate, compressive stress is formed on a contact surface of the glass substrate and the frit according to a thermal property of the applied material (e.g., the frit). As described above, the compressive stress formed inside the glass substrate is temporarily formed, but it can be seen that when the frit is not removed, as illustrated in FIGS. 6 and 7, the compressive stress may be applied as permanent stress. That is, it can be seen that for a crack of the glass substrate existing within a range of the temporary compressive stress, it is possible to prevent or restrict an initially generated crack from being expanded by offsetting the temporarily added tensile stress during the implementing of the curved panel.

The aforementioned substrate for the curved display device may adopt a technique for forming temporary stress within the glass substrate by applying thermal expansion properties of different materials, so that it is possible to form permanent compressive stress at a peripheral portion of the crack of the glass substrate. The inorganic coating part may be applied to a portion to which tensile stress is selectively concentrated. The aforementioned inorganic coating part may continuously block moisture and absorb impact, thereby restricting a crack from being grown.

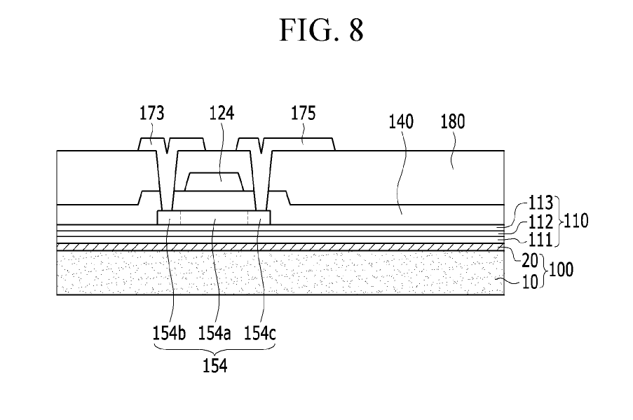

Hereinafter, a display device using the aforementioned substrate for the curved display device is described with reference to FIG. 8.

FIG. 8 is a cross-sectional view illustrating a curved display device according to yet another exemplary embodiment of the present system and method.

A display device according to yet another exemplary embodiment of the present system and method includes the aforementioned substrate 100 for the curved display device.

The substrate 100 for the curved display device includes an alkali-free glass substrate 10 and an inorganic coating part 20 formed on a display surface and/or a lateral surface of the alkali-free glass substrate 10. The alkali-free glass substrate 10 is formed of an alkali-free glass material in which an alkali metal oxide is not contained. In the substrate 100 for the curved display device, it is possible to apply temporary compressive stress, which is exhibited according to a thermal property, into the glass substrate by locally or selectively sintering a material having a relatively larger value of the CTE than that of the alkali-free glass substrate 10 on the surface and/or an edge portion of the alkali-free glass substrate 10. Accordingly, it is possible to prevent an initially generated crack on the surface of the glass from growing, or otherwise slow its growth, or prevent a panel from being damaged due to a crack.

A buffer layer 110 is formed on the substrate 100 for the curved display device. The buffer layer 110 is a sort of blocking layer formed on one surface of the substrate 100 and prevents moisture and oxygen from permeating from the outside, and may be made of, for example, an inorganic material.

The inorganic material may be made of an oxide of a metalloid, such as silicon (Si), a nitride or an oxynitride, an oxide of a metal, such as titanium (Ti), tantalum (Ta), and aluminum (Al), or an oxide, a nitride, or an oxynitride of a combination thereof.

The buffer layer 110 may be a single layer or multilayers. For example, the buffer layer 110 may include a single layer formed of a silicon oxide or a silicon nitride, a dual layer, such as a silicon oxide/silicon nitride, or a triple layer, such as a silicon oxide/silicon nitride/silicon oxide, but the buffer layer 110 is not limited thereto.

The buffer layer 110 may be deposited on the substrate 100 at a temperature of 50° C. to 650° C. by the PECVD method.

A planarization layer 20 is a thin film having Si—O bonding as described above, so that the planarization layer 20 may replace a part or an entirety of the buffer layer 110. Accordingly, the buffer layer 110 may be formed of the small number of stacked layers or be omitted depending on a case.

A semiconductor layer 154 is formed on the substrate 100. The semiconductor layer 154 includes a channel region 154a where an impurity is not doped, and a source region 154b and a drain region 154c where an impurity is doped. The semiconductor layer 154 may include, for example, amorphous silicon, polysilicon, an organic semiconductor, an oxide semiconductor, or a combination thereof.

A gate insulating layer 140 is formed on the semiconductor layer 154. The gate insulating layer 140 is formed on a front surface of the substrate 100, and may be made of, for example, an inorganic material, such as a silicon oxide or a silicon nitride or an organic material, such as polyvinyl alcohol. The gate insulating layer 140 includes contact holes for exposing the source region 154b and the drain region 154c, respectively.

A gate electrode 124 is formed on the gate insulating layer 140. The gate electrode 124 overlaps the channel region 154a of the semiconductor layer 154. A passivation layer 180 is formed on the gate electrode 124. The passivation layer 180 includes contact holes for exposing the source region 154b and the drain region 154c.

A source electrode 173 and a drain electrode 175 are formed on the passivation layer 180. The source electrode 173 is electrically connected with the source region 154b of the semiconductor layer 154 through the contact hole formed in the passivation layer 180 and the gate insulating layer 140, and the drain electrode 175 is electrically connected with the drain region 154c of the semiconductor layer 154 through the contact hole formed in the passivation layer 180 and the gate insulating layer 140.

The semiconductor layer 154, the gate electrode 124, the source electrode 173, and the drain electrode 175 form a thin film transistor TFT.

A pixel electrode (not illustrated) is formed on the thin film transistor, and the pixel electrode is electrically connected with the thin film transistor.

When the display device is an organic light emitting diode display, the display device may further include a common electrode (not illustrated) facing the pixel electrode, and a light emission layer (not illustrated) interposed between the pixel electrode and the common electrode.

In this case, one or more of the pixel electrode and the common electrode may be a transparent electrode, and if the pixel electrode is a transparent electrode, the display device may be a bottom emission type in which light is emitted toward the substrate 100, and if the common electrode is a transparent electrode, the display device may be a top emission type in which light is emitted toward an opposite side of the substrate 100. Further, when all of the pixel electrode and the common electrode are transparent electrodes, the display device may be a dual-side emission type in which light is emitted toward the substrate 100 and an opposite side of the substrate 100.

When the display device is a liquid crystal display, the display device may further include an opposing substrate (not illustrated) facing the substrate 100, and the opposing substrate may include a common electrode, a color filter, and the like. A liquid crystal layer may be interposed between the substrate 100 and the opposing substrate.

While the present system and method are described in connection with exemplary embodiments, the present system and method are not limited to the disclosed embodiments. On the contrary, the present system and method covers various modifications and equivalent arrangements included within the spirit and scope of the appended claims.

### DESCRIPTION OF SYMBOLS

| | |
|---|---|
| 100: Substrate for curved display device | |
| 10: Alkali-free glass substrate | |
| 20: Inorganic coating part | 110: Silicon buffer layer |
| 154: Semiconductor layer | 140: Gate insulating layer |
| 173: Source electrode | 175: Drain electrode |
| 180: Passivation layer | |

What is claimed is:

1. A substrate for a curved display device, comprising:
an alkali-free glass substrate that does not contain an alkali metal oxide; and
an inorganic coating part formed on at least one of a display surface and a lateral surface of the alkali-free glass substrate, and having a larger value of a coefficient of thermal expansion than that of the glass substrate.

2. The substrate of claim 1, wherein:
a value of a coefficient of thermal expansion of the alkali-free glass substrate is 40×10⁻⁷/° C. or lower.

3. The substrate of claim 1, wherein:
a difference in values of the coefficient of thermal expansion between the alkali-free glass substrate and the inorganic coating part is less than 40×10⁻⁷/° C.

4. The substrate of claim 1, wherein:
the inorganic coating part includes a metal, glass, or a combination thereof.

5. The substrate of claim 4, wherein:
the inorganic coating part is formed by sintering frit.

6. The substrate of claim 5, wherein:
the inorganic coating part is formed at an edge portion of the alkali-free glass substrate.

7. The substrate of claim 6, wherein:
the inorganic coating part is locally formed at the edge portion of the alkali-free glass substrate.

8. A method of manufacturing a substrate for a curved display device, the method comprising:
applying an inorganic paste onto at least one of a display surface and a lateral surface of an alkali-free glass substrate that does not contain an alkali metal oxide; and
sintering the inorganic paste,
wherein the inorganic paste contains a component having a larger value of a coefficient of thermal expansion than that of the alkali-free glass substrate.

9. The method of claim 8, wherein:
the inorganic paste is applied onto an edge portion of the alkali-free glass substrate.

10. The method of claim 9, wherein:
the inorganic paste is locally applied onto the edge portion of the alkali-free glass substrate.

11. The method of claim 8, wherein:
the sintering is performed by using a laser heat source.

12. The method of claim 8, wherein:
a value of the coefficient of thermal expansion of the alkali-free glass substrate is 40×10⁻⁷/° C. or lower.

13. The method of claim 8, wherein:
the inorganic paste contains frit.

14. A method of cutting a substrate for a curved display device, the method comprising:
applying an inorganic paste onto a part of a surface of an alkali-free glass substrate that does not contain an alkali metal oxide;
sintering the inorganic paste to form sintered inorganic paste; and
cutting the alkali-free glass substrate along a portion at which the sintered inorganic paste is formed.

15. The method of claim 14, wherein:
the inorganic paste contains frit.

16. A curved display device, comprising:
a substrate for the curved display device;
a thin film transistor positioned on the substrate for the curved display device; and
a pixel electrode connected to the thin film transistor, wherein
the substrate for a curved display device comprising,
an alkali-free glass substrate that does not contain an alkali metal oxide; and
an inorganic coating part formed on at least one of a display surface and a lateral surface of the alkali-free glass substrate, and having a larger value of a coefficient of thermal expansion than that of the glass substrate.

17. The curved display device of claim 16, further comprising:
a common electrode facing the pixel electrode; and
a light emission layer interposed between the pixel electrode and the common electrode.
